(19) United States
(12) Patent Application Publication
(10) Pub. No.: US 2019/0215948 A1
(43) Pub. Date: Jul. 11, 2019

(54) SYSTEMS AND METHODS FOR THERMAL DISSIPATION

(71) Applicant: Searete LLC, Bellevue, WA (US)

(72) Inventors: Daniel Arnitz, Seattle, WA (US); Joseph Hagerty, Seattle, WA (US); Russell J. Hannigan, Sammamish, WA (US); Guy S. Lipworth, Seattle, WA (US); David R. Nash, Arlington, WA (US); Matthew S. Reynolds, Seattle, WA (US); Yaroslav A. Urzhumov, Bellevue, WA (US)

(21) Appl. No.: 15/866,301

(22) Filed: Jan. 9, 2018

(51) Int. Cl. H05K 1/02; H05K 1/18

(52) U.S. Cl. CPC H05K 1/0206; H05K 1/181; H05K 1/0216; H01P 7/065; H05K 2201/10409; H05K 2201/066; H05K 2201/10371; H05K 2201/10545

(57) ABSTRACT

According to various embodiments, heat can be dissipated from a heat producing component mounted on a first side of a printed circuit board through a securing post extending out of the first side of the printed circuit board. The securing post can be configured to attach to a heat sink through a fastening mechanism. Subsequently, the securing post can transfer heat received from the heat producing component to the heat sink as part of dissipating the heat from the heat product component. The securing post can receive heat from the heat producing component through a printed circuit board heat transfer path integrated as part of the printed circuit board. The heat transfer path can include one or more thermal vias and one or more thermally conductive layers used to transfer the heat from the heat producing component to the securing post.

If an Application Data Sheet (ADS) has been filed on the filing date of this application, it is incorporated by reference herein. Any applications claimed on the ADS for priority under 35 U.S.C. §§ 119, 120, 121, or 365(c), and any and all parent, grandparent, great-grandparent, etc. applications of such applications, are also incorporated by reference, including any priority claims made in those applications and any material incorporated by reference, to the extent such subject matter is not inconsistent herewith.

### CROSS-REFERENCE TO RELATED APPLICATIONS

The present application claims the benefit of the earliest available effective filing date(s) from the following listed application(s) (the “Priority Applications”), if any, listed below (e.g., claims earliest available priority dates for other than provisional patent applications or claims benefits under 35 USC § 119(e) for provisional patent applications, for any and all parent, grandparent, great-grandparent, etc. applications of the Priority Application(s)).

### Priority Applications:

If the listings of applications provided above are inconsistent with the listings provided via an ADS, it is the intent of the Applicant to claim priority to each application that appears in the Domestic Benefit/National Stage Information section of the ADS and to each application that appears in the Priority Applications section of this application. All subject matter of the Priority Applications and of any and all applications related to the Priority Applications by priority claims (directly or indirectly), including any priority claims made and subject matter incorporated by reference therein as of the filing date of the instant application, is incorporated herein by reference to the extent such subject matter is not inconsistent herewith.

### TECHNICAL FIELD

This disclosure relates to thermal dissipation for heat producing components. Specifically, this disclosure relates to thermal dissipation for a heat producing component mounted on a first side of a printed circuit board using a securing post extending out from the first side of the printed circuit board upon which the heat producing component is mounted.

### SUMMARY

According to various embodiments, heat can be dissipated from a heat producing component mounted on a first side of a printed circuit board through a securing post extending out of the first side of the printed circuit board. The securing post can be configured to attach to a heat sink through a fastening mechanism. Subsequently, the securing post can transfer heat received from the heat producing component to the heat sink as part of dissipating the heat from the heat product component. The securing post can receive heat from the heat producing component through a printed circuit board heat transfer path integrated as part of the printed circuit board. The heat transfer path can include one or more thermal vias and one or more thermally conductive layers used to transfer the heat from the heat producing component to the securing post.

In various embodiments, heat generated by a heat producing component disposed on a first side of a printed circuit board can be absorbed. Subsequently, the absorbed heat can be transferred to a securing post extending out of the first side of the printed circuit board through a printed circuit board heat transfer path that thermally couples the heat producing component to the securing post, as part of dissipating the heat away from the heat producing component. The heat can be transferred through either or both one or more thermal vias and one or more thermally conductive layers forming, at least in part, the printed circuit board heat transfer path. After being transferred to the securing post, the heat can be transferred from the securing post to a heat sink secured to the printed circuit board through the securing post.

In various embodiments, a printed circuit board that includes one or more heat producing components on a first side of the printed circuit board can be identified. The printed circuit board can include one or more printed circuit board heat transfer paths that thermally couple the one or more heat producing components to one or more securing posts. The securing posts can be disposed on the first side of the printed circuit board and extend out from the first side of the printed circuit board. The heat transfer paths can be configured to transfer heat generated by the one or more heat producing components to the one or more securing posts as part of dissipating the heat away from the one or more heat producing components. A heat sink can be fabricated based on the positions of the one or more securing posts on the first side of the printed circuit board. Subsequently, the heat sink can be secured to the printed circuit board by attaching the heat sink to the one or more securing posts through one or more fastening mechanisms. By securing the heat sink to the printed circuit board through the one or more securing posts, the heat sink can subsequently receive heat generated by the one or more heat producing components through the one or more securing posts.

### BRIEF DESCRIPTION OF THE DRAWINGS

FIG. 1 illustrates a cross sectional view of an example component heat dissipation structure.

FIG. 2 illustrates a cross sectional view of an example multiple component heat dissipation structure.

FIG. 3 depicts a cross sectional view of a structure for dissipating heat from a component using either or both thermal vias and thermally conductive layers.

FIG. 4 depicts a cross sectional view of a structure for dissipating heat from a component through a top of the component.

FIG. 5 depicts a top perspective view of a structure for dissipating heat away from a plurality of heat producing components using one or more heat sinks. The structure includes a printed circuit board.

FIG. 6 is a flowchart of an example method of dissipating heat away from one or more heat producing components using a securing post mounted on a same side of a printed circuit board upon which the heat producing components are mounted.

FIG. 7 is a flowchart of an example method of dissipating heat from one or more heat producing components, at least in part, through one or more posts extending out from a heat sink and contacting the heat producing components.

FIG. 8 is a flowchart of an example method of dissipating heat away from one or more heat producing components using one or more securing posts mounted on a same side of a printed circuit board upon which the heat producing components are mounted.

### DETAILED DESCRIPTION

In various embodiments, one or more heat producing component can be mounted on a first side of a printed circuit board. The first side of the printed circuit board can include one or more securing posts extending out from the first side of the printed circuit board. The securing posts can be configured to attach to one or more heat sinks through one or more fastening mechanisms to secure the one or more heat sinks to the printed circuit board. The one or more heat producing components are thermally coupled to the one or more securing posts through one or more printed circuit board heat transfer paths. The one or more heat producing heat transfer paths can be used to transfer heat generated by the one or more heat producing components to the one or more securing posts. Subsequently, the heat transferred to the one or more securing posts can be transferred to the one or more heat sinks when the heat sinks are attached to the one or more securing posts through the fastening mechanisms. In transferring the heat to securing posts and heat sinks disposed on the same side of the printed circuit board that the heat producing components are mounted, additional components, e.g. antennas, can be mounted on the opposing side of the printed circuit board. More specifically, the additional components can be mounted at opposing positions to positions at which the heat producing components are mounted on the first side of the printed circuit board. Further, in transferring the heat to securing posts and heat sinks disposed on the same side of the printed circuit board that he heat producing components are mounted, an opposing side of the printed circuit board can be covered, e.g. with thermally insulating materials such as a plastic housing or cover.

In certain embodiments, heat generated by one or more heat producing components disposed on a first side of a printed circuit board can be absorbed. The absorbed heat can then be transferred to one or more securing posts extending out of the printed circuit board along the first side of the printed circuit board. The absorbed heat can be transferred from the one or more heat producing components to the one or more securing posts through one or more printed circuit board heat transfer paths integrated as part of the printed circuit board. For example, the absorbed heat can be transferred from the one or more heat producing components to the one or more securing posts using one or more thermally conductive layers and one or more thermal vias.

In various embodiments, a printed circuit board that includes one or more heat producing components on a first side of the printed circuit board can be identified. The printed circuit board can include one or more printed circuit board heat transfer paths that thermally couple the one or more heat producing components to one or more securing posts extending out of the printed circuit board on the first side of the board. One or more heat sinks can be fabricated based on positions of the one or more securing posts on the first side of the printed circuit board. Subsequently, the one or more heat sinks can be secured to the printed circuit board through one or more fastening mechanisms used to attach the one or more heat sinks to the one or more securing posts.

The embodiments of the disclosure will be best understood by reference to the drawings, wherein like parts are designated by like numerals throughout. The components of the disclosed embodiments, as generally described and illustrated in the figures herein, could be arranged and designed in a wide variety of different configurations. Furthermore, the features, structures, and operations associated with one embodiment may be applicable to or combined with the features, structures, or operations described in conjunction with another embodiment. In other instances, well-known structures, materials, or operations are not shown or described in detail to avoid obscuring aspects of this disclosure.

Thus, the following detailed description of the embodiments of the systems and methods of the disclosure is not intended to limit the scope of the disclosure, as claimed, but is merely representative of possible embodiments. In addition, the steps of a method do not necessarily need to be executed in any specific order, or even sequentially, nor need the steps be executed only once.

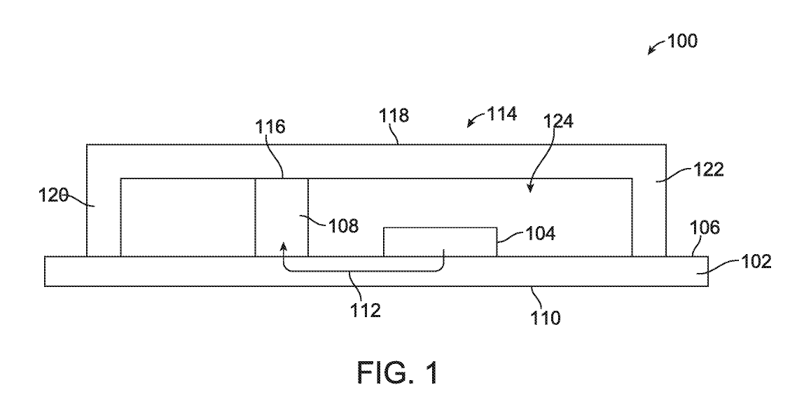

FIG. 1 illustrates a cross sectional view of an example component heat dissipation structure 100. The example component heat dissipation structure 100 shown in FIG. 1 includes a printed circuit board 102. The printed circuit board 102 can be single sided, e.g. include one conductive layer, double sided, e.g. include two conductive layers, or multi-layered, e.g. include multiple conductive layers. For example, the printed circuit board 102 can include multiple conductors on different layers that are laminated together. In another example, the printed circuit board 102 can be comprised of two separate printed circuit boards that may or may not be laminated together. Conductive layers forming the printed circuit board 102 can be electrically coupled together through vertical interconnect accesses (herein referred to as “vias”).

The example component heat dissipation structure 100 shown in FIG. 1 includes a heat producing component 104 mounted to the printed circuit board 102 along a first side of the printed circuit board 106. The heat producing component 104 can be one of a semiconductor device, a sensor, an actuator, a resistive component, a processor, a microcontroller, a regulator, an amplifier, a receiver, a transmitter, a transceiver, a mixer, a transistor, a diode, an LED, an array of LEDs, thyristors, photo cells, a DIAC, a TRIAC, a rectifier, an optocoupler, and a laser. In being mounted to the printed circuit board 102, the printed circuit board 102 can provide mechanical support for the heat producing component 104. Additionally, in being mounted to the printed circuit board 102, the printed circuit board 102 can provide electrical connections for the heat producing component 104. The heat producing component 104 can be mounted to the printed circuit board 102 using an applicable securing mechanism. For example, the heat producing component 104 can be mounted onto the printed circuit board 102 using one or a combination of soldering, gluing, welding, press fitting, bolting, an applicable mounting structure, and screws. For example, the heat producing component 104 can be mounted onto the printed circuit board 102 using sockets and screws.

Additionally, the example component heat dissipation structure 100 shown in FIG. 1 includes a securing post 108. The securing post 108 extends out from the first side of the printed circuit board 106. As a result, the securing post 108 is disposed on the same side of the printed circuit board 102 where the heat producing component 104 is mounted. The securing post can be affixed to the printed circuit board 102 through an applicable securing mechanism. For example, the heat producing component 104 can be affixed to the printed circuit board 102 using one or a combination of soldering, gluing, welding, press fitting, and bolting. Additionally, the securing post 108 can be affixed to the printed circuit board 102 through a coupling mechanism that extends through a second side 110 of the printed circuit board 102. For example, the securing post 108 can be affixed to the first side of the printed circuit board 106 using one or more screws that extend through the printed circuit board 102 from the second side 110 of the printed circuit board 102. In another example, the securing post 108 can be affixed to the first side of the printed circuit board 106 through an applicable mounting mechanism, such as sockets and screws.

In various embodiments, the second side 110 of the printed circuit board 102 has one or more components mounted thereon. For example, the second side 110 of the printed circuit board 102 can support a mounted RF antenna or an RF antenna that is part of the structure of the printed circuit board 102. Further in the example, the second side 110 of the printed circuit board 102 can support a plurality of RF antennas that form an array, e.g. phased array, of RF antennas. Components mounted or structured on the second side 110 of the printed circuit board 102 can prevent affixing of either or both a heat sink and a securing post used to attach the heat sink to the printed circuit board 102 along all or a portion of the second side 110 of the printed circuit board 102. This, in turn, can necessitate disposing one or more heat sinks along the first side of the printed circuit board 106 where the heat producing component 104 is mounted, for purposes of dissipating generated heat away from the heat producing component 104.

The heat producing component 104 can be thermally coupled to the securing post 108 through a printed circuit board heat transfer path 112. The printed circuit board heat transfer path 112 can be integrated as part of the printed circuit board 102. For example, the printed circuit board heat transfer path 112 can be integrated within the printed circuit board 102, e.g. as part of one or more metal layers of the printed circuit board 102. In one example, the printed circuit board heat transfer path 112 can be integrated as part of the printed circuit board 102 on the first side of the printed circuit board 106. In another example, the printed circuit board heat transfer path 112 can be integrated as part of one or more layers of the printed circuit board 102. Specifically, the printed circuit board heat transfer path 112 can be integrated as part of one or more inner or outer copper layers integrated as part of the printed circuit board 102.

By thermally coupling the securing post 108 to the heat producing component 104, the printed circuit board heat transfer path 112 can be used to dissipate heat generated by the heat producing component 104 away from the heat producing component 104. More specifically, the printed circuit board heat transfer path 112 can be used to transfer heat generated by the heat producing component 104 to the securing post 108, as part of dissipating the heat away from the heat producing component 104. For example, the printed circuit board heat transfer path 112 can transfer heat generated by the heat producing component 104 into the printed circuit board along a direction away from and perpendicular to the heat producing component 104. Further in the example, the printed circuit board heat transfer path 112 can subsequently transfer the heat generated by the heat producing component 104 within the printed circuit board 102 along a direction parallel to the first side of the printed circuit board 106. Still further in the example, the printed circuit board heat transfer path 112 can transfer the heat transferred along the direction parallel to the first side of the printed circuit board 106 to the securing post 108 along a direction perpendicular to the first side of the printed circuit board 106 and towards the securing post 108.

In various embodiments, the heat producing component 104 can be thermally coupled to one or more components mounted on the second side 110 of the printed circuit board 102. In being thermally coupled to one or more components mounted on the second side 110 of the printed circuit board 102, the one or more components mounted on the second side 110 of the printed circuit board 102 can receive heat generated by the heat producing component 104, e.g. as part of dissipating the heat away from the heat producing component 104. More specifically, the one or more components on the second side 110 of the printed circuit board 102 can received heat generated by heat producing component 104 that is transferred through at least a portion of the printed circuit board 102 to the second side 110 of the printed circuit board 102.

The heat producing component 104 and one or more components mounted on or integrated as part of the second side 110 of the printed circuit board 102 can be thermally coupled to each other through, at least in part, the printed circuit board heat transfer path 112. Additionally, the heat producing component 104 and one or more components mounted on the second side 110 of the printed circuit board 102 can be thermally coupled to each other through, at least in part, a second printed circuit board heat transfer path separate from or forming part of the printed circuit board heat transfer path 112. For example, the heat producing component 104 can be thermally coupled to an RF antenna mounted on the second side 110 of the printed circuit board 102 through an RF feed connecting the heat producing component 104 to the RF antenna. Further in the example, The RF feed can be used to transfer heat generated by the heat producing component 104 to the RF antenna mounted on the second side 110 of the printed circuit board 102, as part of dissipating heat from the heat producing component 104. In another example, the heat producing component can be thermally coupled to a metal surface forming part of an antenna on the second side 110 of the printed circuit board. Further, the metal surface can form part of the heat transfer path 112 and be used to transfer heat from the heat producing component 104 to the securing post 108.

The securing post 108 can be attachable, potentially removably attachable, to a heat sink 114, included as part of the example component heat dissipation structure 100. All or portions of the heat sink 114 can be thermally conductive and configured to receive heat generated by the heat producing component 104 as part of dissipating the heat away from the heat producing component 104. More specifically, the heat sink 114 can be attached to the securing post 108, subsequently securing the heat sink 114 to the printed circuit board 102. In turn the heat sink 114 can dissipate heat away from the heat producing component 104. In being removably attachable to the heat sink 114, the securing post 108 can be used to secure the heat sink 114 to and unsecure the heat sink 114 from the printed circuit board 102. For example, the heat sink 114 can be unsecured from the printed circuit board 102 by detaching the heat sink 114 from the securing post 108 after the heat sink 114 is attached to the securing post 108.

Either or both the securing post 108 and the heat sink 114 can be used to transfer heat away from the second side 110 of the printed circuit board 102. Specifically, either or both the securing post 108 and the heat sink 114 can receive heat generated from components mounted on or integrated as part of the printed circuit board 102 on the second side 110 of the printed circuit board 102. For example, heat generated by an antenna mounted on the second side 110 of the printed circuit board 102 can be transferred away from the second side 110 of the printed circuit board 102 to the securing post 108 and the heat sink 114. The heat transfer path 112 can be used to transfer heat away from the second side 110 of the printed circuit board 102. For example, a metal surface of an antenna mounted on the second side 110 of the printed circuit board 102 forming part of the heat transfer path 112 can be used to transfer heat generated by the antenna through the heat transfer path 112 to the securing post 108.

The heat sink 114 can be attached to the securing post 108, thereby securing the heat sink 114 to the printed circuit board 102, through a fastening mechanism. A fastening mechanism can include an applicable mechanism for attaching the heat sink 114 to the securing post 108. For example, the heat sink 114 and the securing post 108 can be soldered together. Additionally, a fastening mechanism for attaching the heat sink 114 to the securing post 108 can include an applicable mechanism for removably attaching the heat sink 114 to the printed circuit board. For example, either or both the heat sink 114 to the securing post 108 can include snap fit connectors for removably securing the heat sink 114 to the securing post 108.

In various embodiments, a fastening mechanism for attaching the heat sink 114 to the securing post 108 can include a cavity and a corresponding pin that is thread into the cavity in order to attach the heat sink 114 to the securing post 108. For example, a fastening mechanism can include a screw that extends through the heat sink 114 into a cavity in the securing post 108, included as part of the fastening mechanism, in order to attach the heat sink 114 to the securing post 108. A cavity in the securing post 108 included as part of a fastening mechanism for attaching the heat sink 114 to the securing post 108 can be formed as part of a through-hole that extends into at least a portion of the printed circuit board 102. More specifically, a cavity in the securing post 108 can be formed as a through-hole that extends along the entire height of the securing post 108 and into at least a portion of the printed circuit board 102.

By attaching the heat sink 114 to the securing post 108, heat transferred to the securing post 108 can subsequently be transferred to the heat sink 114. In particular, heat generated by the heat producing component 104 that is transferred to the securing post 108 can be transferred from the securing post 108 to the heat sink 114. Subsequently, the heat sink 114 can dissipate heat received from the securing post 108 through an ambient environment, e.g. as part of dissipating heat from the heat producing component 104.

In various embodiments, at least a portion of either or both the securing post 108 or a fastening mechanism used to attach the heat sink 114 to the securing post 108 are electrically conductive. For example, at least a portion of the securing post 108 and/or a pin forming part of a fastening mechanism for the securing post 108 and the heat sink 114 can be Aluminum or Copper. In being electrically conductive, either or both the securing post 108 and a fastening mechanism used to attach the heat sink 114 to the securing post 108 can serve as electrical connections, e.g. be electrically coupled to the heat producing component 104. For example, a pin of a fastening mechanism used to attach the securing post 108 to the heat sink 114 can, at least in part, serve as a ground connection for the heat producing component 104.

Either or both the securing post 108 and a fastening mechanism used to attach the heat sink 114 to the securing post 108 can be electrically coupled to the heat producing component 104 through, at least, the printed circuit board heat transfer path 112. For example, the printed circuit board heat transfer path 112 can be electrically conductive or include portions that are electrically conductive and serve to electrically couple the securing post 108 to the heat producing component 104. Further in the example, the printed circuit board heat transfer path 112 can electrically couple a pin formed as part of the fastening mechanism to the heat producing component through the securing post 108.

The heat sink 114 and the securing post 108 can contact each other at a securing post contact point 116 formed between a portion of the securing post 108 and a portion of the heat sink 114. More specifically, the securing post contact point 116 is formed between at least a portion of a top of the securing post 108 and a portion of the heat sink 114 when the heat sink 114 is attached to the securing post through a fastening mechanism. In various embodiments a filler material can be disposed between the heat sink 114 and the securing post 108 at the securing post contact point 116. A filler material at the securing post contact point 116 can be either or both a thermally conductive filler and an electrically conductive filler. For example, a filler material disposed at the securing post contact point 116 can include heat sink paste. A filler material at the securing post contact point 116 can serve to or aid in either or both thermally coupling and electrically coupling the heat sink 114 to the securing post 108 and subsequently the heat producing component 104. For example, a filler material at the securing post contact point 116 can transfer heat generated by the heat producing component 104 from the securing post 108 to the heat sink 114, e.g. as part of dissipating the heat from the heat producing component 104.

In various embodiments, at least a portion of the heat sink 114 is electrically conductive. In being electrically conductive, the heat sink 114 can be electrically coupled to the heat producing component 104 and potentially act as an electrical contact for the heat producing component 104. For example, at least a portion of the heat sink 114 can be electrically coupled to the heat producing component 104 and serve as an electrical input for the heat producing component 104. Additionally, at least a portion of the heat sink 114 can be electrically conductive and electrically couple the heat sink 114 to the securing post 108. For example, a portion of the heat sink 114 contacting the securing post 108, e.g. through a filler material, can be electrically conductive and electrically couple the heat sink 114 to the securing post 108. Further in the example, the securing post 108 can be electrically coupled to the heat producing component 104, thereby electrically coupling the heat sink 114 to the heat producing component 104.

The heat sink 114 includes a cover 118, a first post 120, and a second post 122. While the heat sink 114 in the example component heat dissipation structure 100 shown in FIG. 1 includes the first post 120 and the second post 122, in various embodiments, the heat sink 114 can only include one post or include more than two posts. The first post 120 and the second post 122 extend out from the cover 118 and can be configured to come into contact, at least in part, with the first side of the printed circuit board 106 when the heat sink 114 is secured to the printed circuit board 102 through the securing post 108. More specifically, the first post 120 and the second post 122 can have a height dependent on a height of the securing post 108 to cause the first post 120 and the second post 122 to come into contact with the first side of the printed circuit board 106 when the heat sink is attached to the securing post 108. For example, the first post 120 and the second post 122 can have the same height as the securing post 108.

The first post 120 and the second post 122 can provide mechanical rigidity to the component heat dissipation structure 100 by coming into contact with the first side of the printed circuit board 106. For example, by contacting the first side of the printed circuit board 106, the first post 120 and the second post 122 can reduce stress and strain in the heat sink 114 in response to applied mechanical forces. In another example, by contacting the first side of the printed circuit board 106, the first post 120 and the second post 122 can reduce stress and strain in the printed circuit board 102 in response to mechanical forces. Reducing stress and strain in the printed circuit board 102 can help ensure that components mounted to the printed circuit board 102 remain mounted to the printed circuit board 102 when mechanical forces are applied to the component heat dissipation structure 100.

The first post 120 and the second post 122 can either or both electrically couple and thermally couple the heat sink 114 to the printed circuit board 102 and subsequently the heat producing component 104. In thermally coupling the heat sink 114 to the heat producing component 104, either or both the first post 120 and the second post 122 can receive heat generated by the heat producing component 104. More specifically, the printed circuit board heat transfer path 112 can extend through the printed circuit board 102 to either or both the first post 120 and the second post 122. Subsequently, heat generated by the heat producing component 104 can be transferred through the printed circuit board heat transfer path 112 to either or both the first post 120 and the second post 122, e.g. as part of dissipating the heat through the heat sink 114.

In various embodiments, a filler material can be disposed between portions of either or both the first post 120 and the second post 122 and the first side of the printed circuit board 106. More specifically, a filler material can be disposed between bottoms of either or both the first post 120 and the second post 122 and portions of the first side of the printed circuit board 106 that contact the first post 120 and the second post 122 when the heat sink 114 is attached to the securing post 108. A filler material disposed between either or both the first post 120 and the second post 122 and the first side of the printed circuit board 106 can be either or both electrically and thermally conductive. For example, thermal grease can be disposed between the first post 120 and the printed circuit board 106. A filler material disposed between either or both the first post 120 and the second post 122 and the first side of the printed circuit board 106 can serve to or aid in either or both thermally coupling and electrically coupling the heat sink to the printed circuit board 102 and subsequently the heat producing component 104. For example, heat generated by the heat producing component 104 can be transferred to the heat sink 114 though a filler material disposed between the first post 120 and the first side of the printed circuit board 106. A filler material disposed between the first post 120 and the first side of the printed circuit board 106 can serve, at least in part, as a heat shield, chemical shield, mechanical shield, or electromagnetic shield for the heat producing component 104.

The cover 118 of the heat sink 114 can be configured to cover at least a portion of the heat producing component 104 when the heat sink is attached to the securing post 108. Specifically, the cover 118 can be positioned above at least a portion of the first side of the printed circuit board 106 and cover at least a portion of the heat producing component 104 when the heat sink 114 is attached to the securing post 108. In covering at least a portion of the heat producing component 104, the cover 118 of the heat sink 114 can provide mechanical shielding to the heat producing component 104. For example, the cover 118 of the heat sink 114 can block or prevent objects, or materials such as liquids and gases, from coming into contact with the heat producing component 104. Additionally, in covering at least a portion of the heat producing component 104, the cover 118 can provide electromagnetic shielding for the heat producing component 104.

The heat sink 114 can form, at least in part, a cavity 124 around at least a portion of the heat producing component 104. In the example component heat dissipation structure 100, the securing post 108, the cover 118, and the second post 122 form the cavity 124 when the heat sink 114 is attached to the securing post 108. The cavity 124 can include a cavity resonance absorber disposed within the cavity 124. For example, the cavity 124 can include a cavity resonance absorber disposed on a top of the cavity 124 along a bottom portion of the cover 118. A cavity resonance absorber disposed within the cavity 124 can absorb electromagnetic energy emitted by the heat producing component 104 and potentially other components and structures within the cavity 124. For example, a cavity resonance absorber disposed within the cavity 124 can absorb RF energy emitted by the heat producing component 104. A cavity resonance absorber disposed within the cavity 124 can be fabricated from applicable materials for absorbing electromagnetic energy, e.g. a foam and rubber layered structure. In various embodiments, a cavity resonance absorber shown in the cavity 124 can also cover the posts 108, 120, and 122.

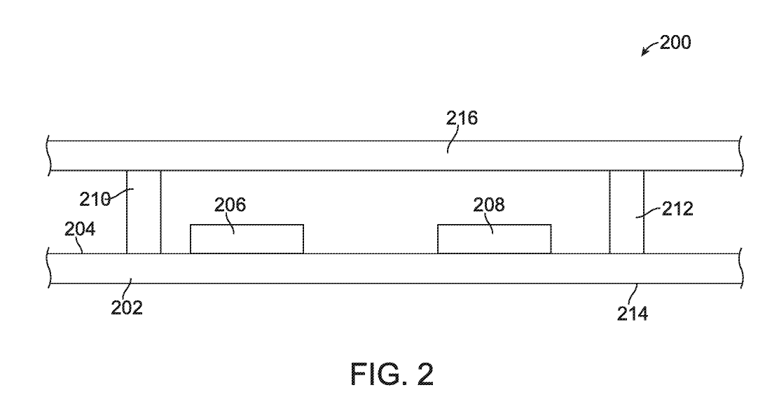

FIG. 2 illustrates a cross sectional view of an example multiple component heat dissipation structure 200. The example multiple component heat dissipation structure 200 shown in FIG. 2 includes a printed circuit board 202. The multiple component heat dissipation structure 200 also includes a first heat producing component 206 and a second heat producing component 208 mounted to the printed circuit board 202 along a first side of the printed circuit board 204. The first heat producing component 206 and the second heat producing component 208 can be either or both electrically and thermally coupled to each other, e.g. through the printed circuit board 202.

The example multiple component heat dissipation structure 200 shown in FIG. 2 includes a first securing post 210 and a second securing post 212 extending out from the printed circuit board 202 along the first side of the printed circuit board 204. While the first heat producing component 206 and the second heat producing component 208 are shown to be positioned in between the first securing post 210 and the second securing post 212, the heat producing components 206 and 208 can be positioned with respect to the securing posts 210 and 212, and vice versa, to form different placement conditions other than the one shown in FIG. 2. For example, the second securing post 212 can be positioned between the first and second heat producing components 206 and 208.

Either or both the first securing post 210 and the second securing post 212 can be electrically coupled to both the first heat producing component 206 and the second heat producing component 208. More specifically, either or both the first securing post 210 and the second securing post 212 can be electrically coupled to both the first heat producing component 206 and the second heat producing component 208 through the printed circuit board 202. In being electrically coupled to both the first heat producing component 206 and the second heat producing component 208, either or both the first securing post 210 and the second securing post 212 can serve as electrical connections for both the first heat producing component 206 and the second heat producing component. For example, the first securing post 210 can be electrically coupled to and serve as a ground connection for both the first heat producing component 206 and the second heat producing component 208.

Additionally, either or both the first securing post 210 and the second securing post 212 can be thermally coupled to both the first heat producing component 206 and the second heat producing component 208. More specifically, either or both the first securing post 210 and the second securing post 212 can be thermally coupled to both the first heat producing component 206 and the second heat producing component 208 through one or more printed circuit board heat transfer paths formed in the printed circuit board 202. In being thermally coupled to both the first heat producing component 206 and the second heat producing component 208, either or both the first securing post 210 and the second securing post 212 can be used to dissipate heat away from the first heat producing component 206 and the second heat producing component 208. Specifically, either or both the first securing post 210 and the second securing post 212 can receive heat generated by both the first heat producing component 206 and the second heat producing component 208 through one or more printed circuit board heat transfer paths.

Either or both the first securing post 210 and the second securing post 212 can be electrically and thermally coupled to components mounted on a second side of the printed circuit board 214 opposing the first side of the printed circuit board 204. In being electrically coupled to components mounted on the second side of the printed circuit board 214, either or both the first securing post 210 and the second securing post 212 can serve as electrical connections for the components. In being thermally coupled to components mounted on the second side of the printed circuit board 214, either or both the first securing post 210 and the second securing post 212 can receive heat generated by the components and structures on the second side of the printed circuit board 214. For example, the first securing post 210 can be thermally coupled through the printed circuit board 202 to antennas on the second side of the printed circuit board 214 and subsequently receive heat generated by the antennas through the printed circuit board 202.

In addition, in being thermally coupled to components mounted on the second side of the printed circuit board 214, the second side of the printed circuit board 214 can receive heat generated by either or both the first heat producing component 206 and the second heat producing component 208. Further, components or structures on the second side of the printed circuit board 214 can subsequently dissipate the heat generated by either or both the first heat producing component 206 and the second heat producing component 208. This can augment a heat transfer path used to transfer heat from the components 206 and 208 to either or both the first securing post 210 and the second securing post 212. For example, either one or both of the heat producing components 206 and 108 and either or both of the securing posts 210 and 212 can be thermally coupled to antennas on the second side of the printed circuit board 214, thus transferring the heat to the antennas. Further in the example, the antennas can thus form part of a thermal dissipation structure.

The example multiple component heat dissipation structure 200 shown in FIG. 2 includes a heat sink 216. The heat sink 216 can be affixed to the first securing post 210 and the second securing post 212 to secure the heat sink 216 to the printed circuit board 202 along the first side of the printed circuit board 204. The heat sink 216 can be affixed to the first securing post 210 and the second securing post 212 through a fastening mechanism. For example, the heat sink 216 can be secured to the first securing post 210 and the second securing post 212 through pins fit into cavities in the first securing post 210 and the second securing post 212. While only a single heat sink 216 is shown, the multiple component heat dissipation structure 200 can include a plurality of separate heat sinks coupled to corresponding securing posts extending out from the first side of the printed circuit board 204.

The heat sink 216 can be electrically coupled to both the first heat producing component 206 and the second heat producing component 208. In being electrically coupled to both the first heat producing component 206 and the second heat producing component 208, the heat sink 216 can serve, at least in part, as an electrical connection for the first heat producing component 206 and the second heat producing component 208. The heat sink 216 can be electrically coupled to both the first heat producing component 206 and the second heat producing component 208 through either or both the first securing post 210 and the second securing post 212. Additionally, the heat sink 216 can be electrically coupled to both the first heat producing component 206 and the second heat producing component 208 through one or more posts extending out from the heat sink 216. For example, one or more posts can extend out from the heat sink and contact the first side of the printed circuit board 204, e.g. through a filler material. Further in the example, the posts can be electrically conductive and serve to electrically couple the heat sink 216 to both the first heat producing component 206 and the second heat producing component 208, e.g. through the printed circuit board 202.

Additionally, the heat sink 216 can be thermally coupled to both the first heat producing component 206 and the second heat producing component 208. In being thermally coupled to both the first heat producing component 206 and the second heat producing component 208, the heat sink 216 can receive heat generated by the first heat producing component 206 and the second heat producing component 208 as part of dissipating heat away from the first heat producing component 206 and the second heat producing component 208. The heat sink 216 can be thermally coupled to both the first heat producing component 206 and the second heat producing component 208 through either or both the first securing post 210 and the second securing post 212. Further, the heat sink 216 can be thermally coupled to both the first heat producing component 206 and the second heat producing component 208 through posts extending out from the heat sink 216. For example, the heat sink 216 can be thermally coupled to the first heat producing component 206 and the second heat producing component 208 through one or more posts extending out from the heat sink 216 and contacting, e.g. through a filler material, the first side of the printed circuit board 204.

The heat sink 216 can be either or both thermally and electrically coupled to one or more components mounted on the second side of the printed circuit board 214. In being thermally coupled to one or more components on the second side of the printed circuit board 214, the heat sink 216 can receive heat generated by the one or more components as part of dissipating the heat from the components. In being electrically coupled to one or more components on the second side of the printed circuit board 214, the heat sink 216 can serve as an electrical connection for the components. The heat sink 216 can be electrically and/or thermally coupled to one or more components on the second side of the printed circuit board 214 through either or both the first securing post 210 and the second securing post 212. Additionally, the heat sink 216 can be electrically and/or thermally coupled to one or more components on the second side of the printed circuit board 214 through posts extending out from the heat sink 216 and contacting, e.g. through a filler material, the first side of the printed circuit board 204.

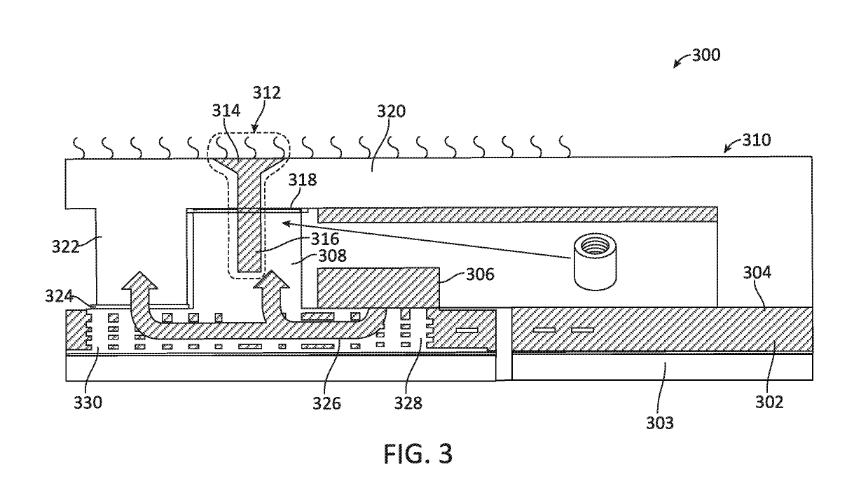

FIG. 3 depicts a cross sectional view of a structure 300 for dissipating heat from a component using either or both thermal vias and thermally conductive layers. The structure 300 includes a printed circuit board 302 with a heat producing component 306 mounted onto a first side of the printed circuit board 304. The structure 300 also includes a securing post 308 extending out from the first side of the printed circuit board 304. Further, the structure 300 also includes a layer 303. The layer 303 can be included as part of the printed circuit board 302 or be a separate object or layer attached to the printed circuit board 302, e.g. an antenna. In certain embodiments, the layer 303 can be separate from a thermal transfer path used to transfer heat through the printed circuit board 302.

The securing post 308 is attached to a heat sink 310 through a fastening mechanism 312, thereby securing the heat sink 310 to the printed circuit board 302. The fastening mechanism 312 includes a screw 314 that extends through the heat sink 310 and is fit into a cavity 316 within the securing post 308. In receiving the screw 314 in the cavity 316, the securing post 308 can be formed, at least in part, from a screw terminal. The cavity 316 can be a threaded or unthreaded cavity for receiving the screw 314. The fastening mechanism 312, including the screw 314 and the cavity 316 can be used to align the heat sink 310 on the printed circuit board 302. Additionally, the fastening mechanism 312, including the screw 314, can serve as an electrical contact for the heat producing component 306 and other components mounted to the printed circuit board 302.

A filler material 318 can be disposed between the heat sink 310 and a top of the securing post 308. The filler material 318 can be either or both an electrically and thermally conductive material that either or both thermally couples and electrically couples, at least in part, the heat sink 310 to the securing post 308. Additionally, the heat sink 310 and the securing post 308 can be either or both electrically and thermally coupled together through physical contacts between the heat sink 310 and the securing post 308, e.g. at a top of the securing post 308.

The heat sink 310 includes a cover 320 and a post 322 that extends down from the cover 320 to contact the first side of the printed circuit board 304. The post 322 contacts the first side of the printed circuit board 304 through a filler material 324. While the post 322 is shown to contact the first side of the printed circuit board 304 through a filler material, in certain embodiments, the post can contact the first side of the printed circuit board 304 directly, e.g. absent a filler material. The filler material 324 can be either or both an electrically and thermally conductive material that either or both thermally couples and electrically couples, at least in part, the heat sink 310 to the printed circuit board 302. Additionally, the heat sink 310 and the printed circuit board can be either or both electrically and thermally coupled together through physical contacts between the bottom of the post 322 and the first side of the printed circuit board 304.

The structure 300 includes a printed circuit board heat transfer path 326. The printed circuit board heat transfer path 326 includes thermal vias 328 and thermally conductive layers 330. While the printed circuit board heat transfer path 326 in the example structure shown in FIG. 3 includes a plurality of thermal vias 328, in various embodiments, the printed circuit board heat transfer path 326 can include only one thermal via. Additionally, while the printed circuit board heat transfer path 326 in the example structure shown in FIG. 3 includes a plurality of thermally conductive layers 330, in various embodiments, the printed circuit board heat transfer path 326 can include only one thermally conductive layer.

The thermally conductive layers 330 are formed on or within the printed circuit board 302. For example, the thermally conductive layers 330 can be inner layers formed within the interior of the printed circuit board 302. In another example, the thermally conductive layers 330 are outer layers formed along the outside of the printed circuit board, e.g. along the first side of the printed circuit board 302. The thermally conductive layers 330 can be formed from an applicable thermally conductive material, e.g. copper.

In various embodiments, the thermally conductive layers 330 are electrically conductive. In being electrically conductive, the thermally conductive layers 330 can serve as electrical interconnects between components mounted to the printed circuit board 302. For example the thermally conductive layers 330 can serve as electrical interconnects between power amplifiers mounted on the printed circuit board 302. Additionally, in being electrically conductive, the thermally conductive layers 330 can electrically couple either or both the securing post 308 and the heat sink 310 to the heat producing component 306.

The thermally conductive layers 330 are formed parallel to the first side of the printed circuit board 304. As a result, the thermally conductive layers 330 can transfer heat generated by the heat producing component 306 in a direction parallel to the first side of the printed circuit board 304. More specifically, the thermally conductive layers 330 can transfer heat generated by the heat producing component 306 in a direction parallel to the first side of the printed circuit board 304 towards either or both the securing post 308 and the post 322 of the heat sink 310.

The thermal vias 328 are formed in the printed circuit board 302. For example, the thermal vias 328 can be formed within the interior of the printed circuit board 302. In another example, the thermal vias 328 are formed within the interior of the printed circuit board 302 and extend to the first side of the printed circuit board 304.

In various embodiments, the thermal vias 328 are either or both electrically conductive and thermally conductive. For example, the thermal vias 328 can be filled with either or both an electrically conductive or thermally conductive material, e.g. copper. In being electrically conductive, the thermal vias 328 can electrically couple either or both the securing post 308 and the heat sink 310 to the heat producing component 306. In being thermally conductive, the thermal vias 328 can thermally couple either or both the securing post 308 and the heat sink 310 to the heat producing component 306.

The thermal vias 328 are formed perpendicular to the first side of the printed circuit board 304. As a result, the thermal vias 328 can transfer heat generated by the heat producing component 306 in a direction perpendicular to the first side of the printed circuit board 304. For example, the thermal vias 328 can transfer heat generated by the heat producing component 306 away from the heat producing component 306 that is a direction that is perpendicular to the first side of the printed circuit. In another example, the thermal vias 328 can transfer heat generated by the heat producing component 306 towards either or both the securing post 308 and the heat sink 310 in a direction that is perpendicular to the first side of the printed circuit board 304.

In transferring heat using the printed circuit board heat transfer path 326, the thermal vias 328 around the heat producing component 306 can receive heat generated by the heat producing component 306. The thermal vias 328 can then transfer the heat in a direction perpendicular to the first side of the printed circuit board 304 away from the heat producing component 306. The thermally conductive layers 330 can receive the heat from the thermal vias 328 and subsequently transfer the heat away from the heat producing component 306 in a direction that is perpendicular to the first side of the printed circuit board 304. The thermal vias 328 disposed around either or both the securing post 308 and the post 322 of the heat sink 310 can receive the heat from the thermally conductive layers 330. Subsequently, the thermal vias 328 can transfer the heat in a direction towards the first side of the printed circuit board 304 and perpendicular to the first side of the printed circuit board 304 to transfer the heat into either or both the securing post 308 and the heat sink 310.

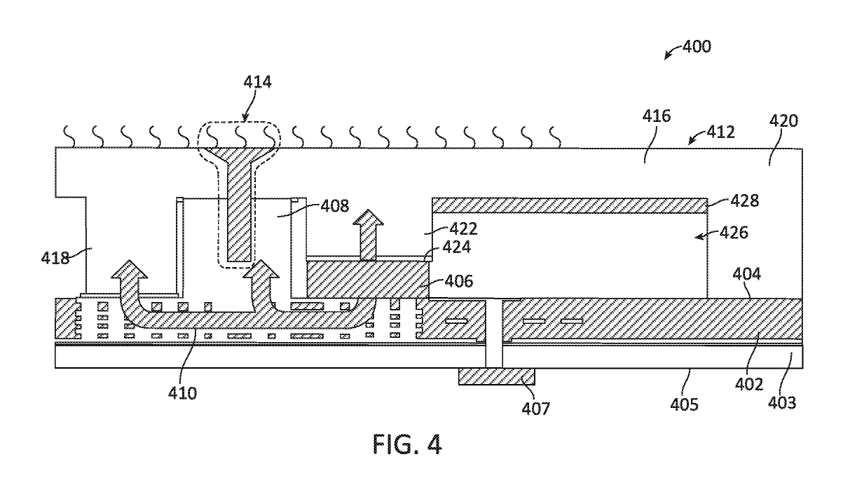

FIG. 4 depicts a cross sectional view of a structure 400 for dissipating heat from a component through a top of the component. The structure 400 includes a printed circuit board 402 with a heat producing component 406 mounted onto a first side of the printed circuit board 404 and a component 407 mounted on a second side of the printed circuit board 405. Further, the structure 400 also includes a layer 403. The layer 403 can be included as part of the printed circuit board 402 or be a separate object or layer attached to the printed circuit board 402, e.g. an antenna. In certain embodiments, the layer 403 can be separate from a thermal transfer path used to transfer heat through the printed circuit board 402.

The structure 400 also includes a securing post 408 extending out from the first side of the printed circuit board 404. The securing post 408 can be soldered to the printed circuit board 402 along the first side of the printed circuit board 404. This decreases an amount of thermal resistance between the securing post 408 and the printed circuit board 402 to allow for increased heat flow of heat generated by the heat producing component 406. More specifically, soldering the securing post 408 to the printed circuit board 402 can increase a heat flow of heat through a printed circuit board heat transfer path 410 thermally coupling the securing post to the heat producing component 406.

A heat sink 412 is attached to the securing post 408 through a fastening mechanism 414. The heat sink 412 includes a cover 416. Additionally the heat sink 412 includes a first post 418, a second post 420, and a third post 422. The first post 418 and the second post 420 extend out of the cover 416 to contact the first side of the printed circuit board 404. In contacting the printed circuit board 402, the first post 418 can receive heat generated by the heat producing component, e.g. through the printed circuit board heat transfer path 410. The second post 420, in contacting the printed circuit board 402 can serve as an electrical contact and shield for the printed circuit board 402 and components mounted thereon. For example, the second post 420 can serve as a ground connection for the heat producing component 406.

The third post 422 extends out of the cover 416 and comes into contact with at least a portion of the heat producing component 424, e.g. a top of the heat producing component. In coming into contact with the heat producing component 406, the third post 422 can receive heat generated by the heat producing component 406, e.g. as part of dissipating heat from the heat producing component 406. The third post 422 can receive heat from the heat producing component 406 concurrently with other portions of the heat sink 412, e.g. through the securing post 408 or at the first post 418. As a result, more heat can be dissipated from the heat producing component 406 and potentially at faster dissipation rates. A filler material can be disposed between third post 422 and at least a portion of the heat producing component 406. A filler material can be either or both an electrically and thermally conductive material configured to further thermally and/or electrically couple the third post 422 to the heat producing component 406. For example, heat sink paste can be disposed between the third post 422 and the heat producing component to reduce thermal resistance between the third post 422 and the heat producing component 406.

In the example structure 400 shown in FIG. 4, the heat sink forms a cavity 426. The structure 400 includes a cavity resonance absorber 428 disposed within the cavity 426. The cavity resonance absorber 428 can absorb energy emitted within the cavity 426. For example, the cavity resonance absorber 428 can absorb electromagnetic energy emitted by either or both the heat producing component 406 and the component 407 mounted on the second side of the printed circuit board 405.

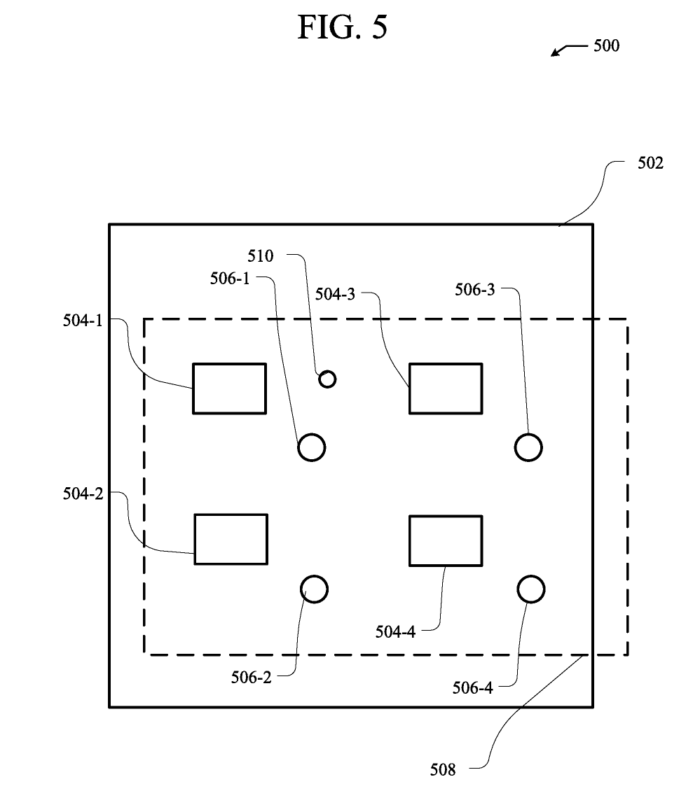

FIG. 5 depicts a top perspective view of a structure 500 for dissipating heat from a plurality of heat producing components using one or more heat sinks. The structure 500 includes a printed circuit board 502. The printed circuit board 502 includes a first heat producing component 504-1, a second heat producing component 504-2, a third heat producing component 504-3, and a fourth heat producing component 504-4, hereinafter referred to as “heat producing components 504.” The heat producing components 504 are mounted onto the printed circuit board 502 on a first side of the printed circuit board.

The structure 500 also includes a first securing post 506-1, a second securing post 506-2, a third securing post 506-3, and a fourth securing post 506-4 (hereinafter referred to as “securing posts 506”. The securing posts 506 are mounted to the printed circuit board 502 along a first side of the printed circuit board using one or a combination of soldering, gluing, welding, press fitting, and bolting. Each securing post of the securing posts 506 can correspond to one or a combination of the heat producing components 504. For example, the first securing post can correspond to the first heat producing component 504-1. In corresponding to the heat producing components 504, the securing posts 506 can be either or both thermally and electrically coupled to the corresponding heat producing components 504, e.g. through a printed circuit board heat transfer path. For example, the first securing post 506-1 can receive heat generated by the first heat producing component 504-1 through a printed circuit board heat transfer path.

The securing posts 506 are configured to attach to one or more heat sinks 508 through a fastening mechanism. In attaching to one or more heat sinks 508, the securing posts 506 can transfer heat generated by the heat producing components 504. More specifically, the heat generated by the heat producing components 504 can be used to dissipate the heat away from the heat producing components 504 along a same side of the printed circuit board where the heat producing components are mounted.

The printed circuit board 502 can include one or more touch-down areas 510. The one or more touch-down areas 510 can include areas that serve as contacts to either or both thermally couple and electrically couple posts extending out from the one or more heat sinks 508 to the printed circuit board 502. For example, the one or more touch-down areas 510 can be metal pads that are configured to electrically couple electrically conductive posts of the one or more heat sinks to the printed circuit board 502. A filler material can be disposed between the one or more touch-down areas 510 and posts to aid in either or both electrically and thermally coupling the one or more touch-down areas 510 to posts extending out from the one or more heat sinks 508.

In various embodiments, the securing posts 506 can serve as electrical connections for the corresponding heat producing components 504. More specifically, the securing posts 506 can serve as electrical connections for the corresponding heat producing components 504 through the printed circuit board 502, e.g. through one or more printed circuit board heat transfer paths coupling the securing posts 506 to the heat producing components 504. Additionally, in various embodiments, the one or more heat sinks 508 can serve as electrical connections for the heat producing components 504. More specifically, the one or more heat sinks 508 can serve as electrical connections for the heat producing components 504 through the securing posts 506.

Either or both the heat producing components 504 and the securing posts 506 can be positioned on the printed circuit board according to the one or more heat sinks 508 attached or that will be attached to the printed circuit board 502. For example, the heat producing components 504 and the securing posts 506 can be positions to allow for posts included as part of the one or more heat sinks to physically contact either or both the printed circuit board 502 and the heat producing components 504.

The one or more heat sinks 508 can be shaped and fabricated based on positions at which either or both the heat producing components 504 and the securing posts 506 are mounted onto the printed circuit board 502. For example, the one or more heat sinks 508 can be fabricated to attach to the securing posts 506 based on the positions at which the securing posts 506 are mounted onto the printed circuit board 502. Further, the one or more heat sinks 508 can be shaped and fabricated based on positions at which the one or more touch-down areas 510 are formed on the printed circuit board 502. For example, posts in the one or more heat sinks 508 can be formed at positions to contact the one or more touch-down areas 510 when the one or more heat sinks 508 are secured to the printed circuit board 502 through the one or more securing posts 506.

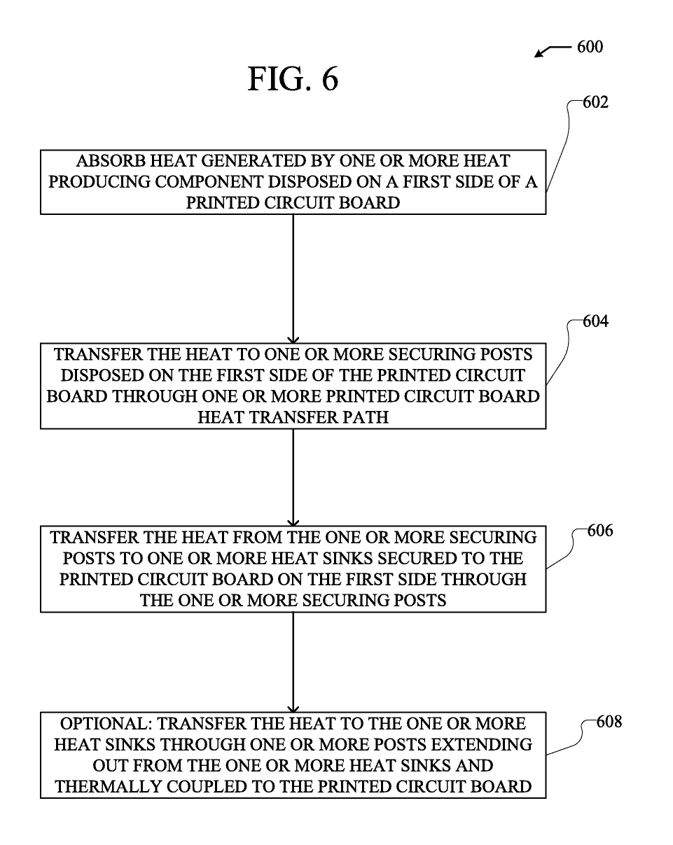

FIG. 6 is a flowchart 600 of an example method of dissipating heat away from one or more heat producing components using a securing post mounted on a same side of a printed circuit board upon which the heat producing components are mounted. At step 602, heat generated by one or more heat producing components disposed on a first side of a printed circuit board is absorbed. More specifically, heat produced by one or more heat producing components disposed on a first side of a printed circuit board can be absorbed, at least in part, by the printed circuit board itself. For example, heat produced by one or more heat producing components can be absorbed at the first side of a printed circuit board through one or more printed circuit board heat transfer paths formed in the printed circuit board.

At step 604, the heat is transferred to one or more securing posts disposed on the first side of the printed circuit board through one or more printed circuit board heat transfer paths. The heat can be transferred through the one or more printed circuit board heat transfer paths using one or more thermal vias and one or more thermally conductive layers forming the printed circuit board heat transfer paths. For example, one or more thermal vias can transfer the heat to one or more thermally conductive layers. Further in the example, the heat can be transferred from the one or more thermally conductive layers to the one or more securing posts through an additional one or more thermal vias.

At step 606, the heat is transferred from the one or more securing posts to one or more heat sinks secured to the printed circuit board on the first side of the printed circuit board through the one or more securing posts. In various embodiments, the heat can be transferred from the one or more securing posts to one or more heat sinks, at least in part, through fastening mechanisms used to attach the one or more heat sink to the one or more securing posts. In transferring the heat to one or more heat sinks attached to the one or more securing posts disposed on the first side of the printed circuit board, the heat is dissipated away from the one or more heat producing components to structures on the first side of the printed circuit board upon which the heat producing components are mounted.

At step 608, optionally, the heat is transferred to the one or more heat sinks through one or more posts extending out from the one or more heat sinks and thermally coupled to the printed circuit board, e.g. the post 322 shown in FIG. 3. The heat can be transferred to one or more posts extending out from the one or more heat sinks and thermally coupled to the one or more heat producing components, through the one or more printed circuit board heat transfer paths. Additionally, the heat can be transferred to one or more posts extending out from the one or more heat sinks through layers of thermally conductive filler materials disposed between the posts and the first side of the printed circuit board, e.g. the one or more touch-down areas 510.

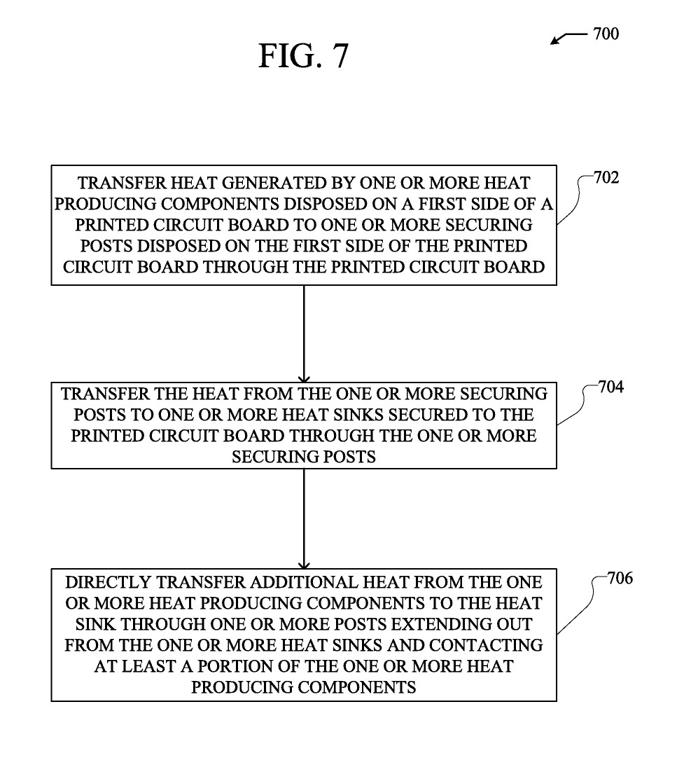

FIG. 7 is a flowchart 700 of an example method of dissipating heat from one or more heat producing components, at least in part, through one or more posts extending out from a heat sink and contacting the heat producing components. At step 702, heat generated by one or more heat producing components disposed on a first side of a printed circuit board is transferred to one or more securing posts disposed on the first of the printed circuit board. The heat is transferred to the one or more securing posts through the printed circuit board. More specifically, the heat can be transferred to the one or more securing posts on the first side of a printed circuit board from one or more heat producing components on the first side of the printed circuit board through one or more printed circuit board heat transfer paths.

At step 704, the heat is transferred from the one or more securing posts to one or more heat sinks secured to the printed circuit board on the first side of the printed circuit board through the one or more securing posts. Additionally, the heat can be transferred from the one or more securing posts to one or more heat sinks through fastening mechanisms used to attach the one or more heat sinks to the one or more securing posts. Further, the heat can be transferred from the one or more securing posts to one or more heat sinks through a thermally conductive filler material disposed between the one or more heat sinks and the one or more securing posts.

At step 706, the additional heat from the one or more heat producing components is directly transferred to the one or more heat sinks through one or more posts extending out from the one or more heat sinks and contacting at least a portion of the one or more heat producing components. In directly transferring heat to the heat sink through the posts contacting the heat producing components while also transferring heat to the heat sinks from the securing posts, a greater amount of heat can be dissipated from the heat producing components. The one or more posts extending out of the one or more heat sinks and contacting at a portion of the one or more heat producing components can contact the components through a filler material disposed between the components and the posts.

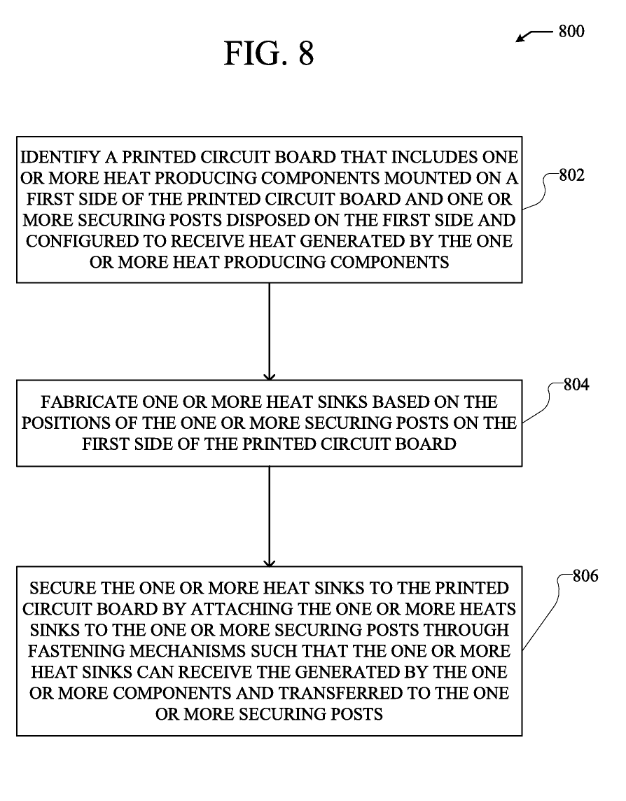

FIG. 8 is a flowchart 800 of an example method of dissipating heat away from one or more heat producing components using a securing post mounted on a same side of a printed circuit board where the heat producing components are mounted. At step 802, a printed circuit board including one or more heat producing components mounted on a first side of the printed circuit board is identified. Additionally, at step 802, the printed circuit board is identified based on one or more securing posts disposed on the first side of the printed circuit board that are configured to receive heat generated by the one or more heat producing components. In identifying the printed circuit board, positions of the heat producing components mounted on the first side of the printed circuit board can be identified. Additionally, in identifying the printed circuit board, positions of the one or more securing posts on the first side of the printed circuit board can be identified.

At step 804, one or more heat sinks are fabricated based on the positions of the one or more securing posts on the first side of the printed circuit board. More specifically, the one or more heat sinks can be fabricated with fastening mechanisms at positions in the one or more heat sinks corresponding to the positions of the one or more securing posts on the first side of the printed circuit board. For example, the one or more heat sinks can be fabricated with fastening mechanisms to allow the one or more heat sinks to attach to the one or more securing posts based on the positions of the securing posts on the first side of the printed circuit board.

In various embodiments, the one or more heat sinks can be fabricated based on positions of one or more touch down areas disposed on the first side of the printed circuit board. More specifically, posts of the one or more heat sinks can be fabricated based on positions of one or more touch down areas disposed on the first side of the printed circuit board. For example, posts of the one or more heat sinks can be fabricated at positions on the one or more heat sinks to come into contact with the one or more touch down areas when the one or more heat sinks are attached to the one or more securing posts.

In certain embodiments, the one or more heat sinks can be fabricated based on the positions of the one or more heat producing components on the first side of the printed circuit board. More specifically, posts of the one or more heat sinks can be fabricated based on the positions of the one or more heat producing components on the first side of the printed circuit board. For example, posts of the one or more heat sinks can be fabricated at positions to contact at least portions of tops of the heat producing components when the one or more heat sinks are attached to the one or more securing posts.

At step 806, the one or more heat sinks are secured to the printed circuit board by attaching the one or more heat sinks to the one or more securing posts through one or more fastening mechanisms. Further, the one or more heat sinks can be attached to the one or more securing posts to allow the one or more heat sinks to receive heat generated by the one or more heat producing components that is transferred to the one or more securing posts. For example, the one or more heat sinks can be attached to the one or more securing posts to receive heat transferred to the posts through one or more printed circuit board heat transfer paths. In various embodiments, the one or more heat sinks can receive heat generated by the one or more heat producing components from the securing posts through one or more fastening mechanisms used to attach the one or more heat sinks to the one or more securing posts.

The example structures shown herein can be configured or included as part of systems configured to wirelessly transfer power using radio frequency (herein referred to as “RF”) signals. Specifically, the various components mounted on the printed circuit boards can include components used in wirelessly transferring power using RF signals. For example, the components can include power amplifiers for amplifying RF signals and antennas for transmitting the RF signals wirelessly. Additionally, the components mounted on the printed circuit board can include components for wirelessly transferring power through a steerable beam of RF energy. For example, the components can include phase shifters and antennas forming a phased array that in combination can transmit a steerable beam of RF energy to transfer power wirelessly.

This disclosure has been made with reference to various exemplary embodiments including the best mode. However, those skilled in the art will recognize that changes and modifications may be made to the exemplary embodiments without departing from the scope of the present disclosure. For example, various operational steps, as well as components for carrying out operational steps, may be implemented in alternate ways depending upon the particular application or in consideration of any number of cost functions associated with the operation of the system, e.g., one or more of the steps may be deleted, modified, or combined with other steps.

While the principles of this disclosure have been shown in various embodiments, many modifications of structure, arrangements, proportions, elements, materials, and components, which are particularly adapted for a specific environment and operating requirements, may be used without departing from the principles and scope of this disclosure. These and other changes or modifications are intended to be included within the scope of the present disclosure.

The foregoing specification has been described with reference to various embodiments. However, one of ordinary skill in the art will appreciate that various modifications and changes can be made without departing from the scope of the present disclosure. Accordingly, this disclosure is to be regarded in an illustrative rather than a restrictive sense, and all such modifications are intended to be included within the scope thereof. Likewise, benefits, other advantages, and solutions to problems have been described above with regard to various embodiments. However, benefits, advantages, solutions to problems, and any element(s) that may cause any benefit, advantage, or solution to occur or become more pronounced are not to be construed as a critical, a required, or an essential feature or element. As used herein, the terms “comprises,” “comprising,” and any other variation thereof, are intended to cover a non-exclusive inclusion, such that a process, a method, an article, or an apparatus that comprises a list of elements does not include only those elements but may include other elements not expressly listed or inherent to such process, method, system, article, or apparatus. Also, as used herein, the terms “coupled,” “coupling,” and any other variation thereof are intended to cover a physical connection, an electrical connection, a magnetic connection, an optical connection, a communicative connection, a functional connection, and/or any other connection.

Those having skill in the art will appreciate that many changes may be made to the details of the above-described embodiments without departing from the underlying principles of the invention. The scope of the present invention should, therefore, be determined only by the following claims.

1. A system comprising:
a heat producing component disposed on a first side of a printed circuit board;
a securing post extending out from the first side of the printed circuit board in a direction that is perpendicular to the first side of the printed circuit board, wherein the securing post is configured to attach to a heat sink through a fastening mechanism to secure the heat sink to the printed circuit board; and
a printed circuit board heat transfer path thermally coupling the heat producing component to the securing post by transferring heat generated by the heat producing component to the securing post, wherein the printed circuit board heat transfer path is integrated as part of the printed circuit board and includes one or more thermal vias extending perpendicular to the first side of the printed circuit board through at least a portion of a thickness of the printed circuit board and one or more thermally conductive layers extending parallel to the first side of the printed circuit board and the one or more thermally conductive layers are configured to transfer the heat generated by the heat producing component in a direction parallel to the first side of the printed circuit board into at least a portion of the one or more thermal vias and the at least the portion of the one or more thermal vias are configured to transfer the heat generated by the heat producing component and received from the one or more thermally conductive layers to the securing post in a direction perpendicular to the first side of the printed circuit board.

2. Canceled

3. The system of claim 1, wherein at least another portion of the one or more thermal vias are configured to transfer the heat generated by the heat producing component in a direction perpendicular to the first side of the printed circuit board into the one or more thermally conductive layers and the one or more thermally conductive layers are configured to transmit the heat generated by the heat producing component and received from the at least another portion of the one or more thermal vias to the securing post in a direction parallel to the first side of the printed circuit board.

4. The system of claim 3, wherein the one or more thermally conductive layers are configured to transmit the heat generated by the heat producing component and received from the at least another portion of the one or more thermal vias to the first side of the printed circuit board through an additional portion of the one or more thermal vias, the additional portion of the one or more thermal vias configured to receive the heat generated by the heat producing component from the one or more thermally conductive layers and transmit the heat received from the one or more thermally conductive layers to the first side of the printed circuit board in a direction towards and perpendicular to the first side of the printed circuit board.

5. The system of claim 1, wherein the heat producing component is a power amplifier.

6. The system of claim 5, wherein the power amplifier is configured for wireless power transfer.

7. The system of claim 1, wherein the heat producing component includes at least one of a semiconductor device, a sensor, an actuator, a resistive component, a processor, a microcontroller, a regulator, an amplifier, a receiver, a transmitter, a transceiver, a mixer, a transistor, a diode, an LED, an array of LEDs, thyristors, photo cells, a DIAC, a TRIAC, a rectifier, an optocoupler, and a laser.

8. The system of claim 1, further comprising a component mounted on a second side of the printed circuit board opposing the first side of the printed circuit board, the component mounted to the printed circuit board on the second side of the printed circuit board at a position, at least in part, opposing the heat producing component and preventing mounting of the heat sink on or above, at least in part, the position opposing the heat producing component.

9. The system of claim 8, wherein the component is an antenna.

10. The system of claim 9, wherein the antenna is configured to wirelessly transfer power using the heat producing component.

11. The system of claim 2, wherein the one or more thermal vias are filled with a thermally conductive material.

12. The system of claim 1, wherein the fastening mechanism of the securing post includes a cavity for receiving a screw to couple the heat sink to the securing post and to secure the heat sink to the printed circuit board.

13. The system of claim 12, wherein the cavity of the securing post is part of a through-hole extending into the printed circuit board for receiving a screw to couple the heat sink to the securing post and the printed circuit board through the cavity.

14. The system of claim 1, wherein the securing post is coupled to the printed circuit board along the first side of the printed circuit board using at least one of soldering, gluing, welding, press fitting, and bolting.

15. The system of claim 1, wherein at least a portion of the securing post is electrically conductive.

16. The system of claim 15, wherein the securing post is electrically coupled to the heat producing component and serves as an electrical connection for the heat producing component.

17. The system of claim 1, wherein the heat producing component is included as part of a plurality of heat producing components disposed on the first side of the printed circuit board.

18. The system of claim 17, wherein the printed circuit board heat transfer path thermally couples the plurality of heat producing components to the securing post by transferring heat generated by the plurality of heat producing components to the securing post.

19. The system of claim 17, wherein the securing post is included as part of a plurality of securing posts disposed on the first side of the printed circuit board and the plurality of securing posts are configured to transfer heat generated by the plurality of heat producing components away from the heat producing components to one or a plurality of heat sinks including the heat sink.

20. The system of claim 19, wherein the one or a plurality of heat sinks are mounted to the printed circuit board along the first side of the printed circuit board.

21. The system of claim 8, further comprising another heat transfer path thermally coupling the heat producing component to a portion of the second side of the printed circuit board, the another heat transfer path configured to transfer the heat generated by the heat producing component to the second side of the printed circuit board.

22. The system of claim 1, wherein the securing post is coupled to the printed circuit board along the first side of the printed circuit board through a coupling mechanism extending through a second side of the printed circuit board opposing the first side of the printed circuit board.

23. The system of claim 1, wherein the securing post is electrically coupled to one or more additional components separate from the heat producing component and serves as an electrical connection for the one or more additional components.

24. The system of claim 21, wherein the another heat transfer path thermally couples the heat producing component to an antenna disposed on the second side of the printed circuit board, the antenna configured to receive the heat generated by the heat producing component through the another heat transfer path as part of dissipating the heat generated by the heat producing component.

25. The system of claim 21, wherein the another heat transfer path is configured to transfer heat generated at the second side of the printed circuit board to the securing post on the first side of the printed circuit board.

26-65. (canceled)

66. A method comprising:
absorbing heat generated by a heat producing component disposed on a first side of a printed circuit board; and
transferring the heat generated by the heat producing component to a securing post through a printed circuit board heat transfer path thermally coupling the heat producing component to the securing post, the securing post configured to attach to a heat sink through a fastening mechanism to secure the heat sink to the printed circuit board, wherein the printed circuit board heat transfer path is integrated as part of the printed circuit board and includes one or more thermal vias extending perpendicular to the first side of the printed circuit board through at least a portion of a thickness of the printed circuit board and one or more thermally conductive layers extending parallel to the first side of the printed circuit board and the one or more thermally conductive layers are configured to transfer the heat generated by the heat producing component in a direction parallel to the first side of the printed circuit board into at least a portion of the one or more thermal vias and the at least the portion of the one or more thermal vias are configured to transfer the heat generated by the heat producing component and received from the one or more thermally conductive layers to the securing post in a direction perpendicular to the first side of the printed circuit board.

67. (canceled)

68. The method of claim 66, wherein the heat transfer path is formed by at least another portion of the one or more thermal vias configured to transfer the heat generated by the heat producing component in a direction perpendicular to the first side of the printed circuit board into the one or more thermally conductive layers and the one or more thermally conductive layers are configured to transmit the heat generated by the heat producing component and received from the at least another portion of the one or more thermal vias to the securing post in a direction parallel to the first side of the printed circuit board.

69. The method of claim 68, wherein the one or more thermally conductive layers are configured to transmit the heat generated by the heat producing component and received from the at least another portion of the one or more thermal vias to the first side of the printed circuit board through an additional portion of the one or more thermal vias, the additional portion of the one or more thermal vias configured to receive the heat generated by the heat producing component from the one or more thermally conductive layers and transmit the heat received from the one or more thermally conductive layers to the first side of the printed circuit board in a direction towards and perpendicular to the first side of the printed circuit board.

70. The method of claim 66, wherein the heat producing component is a power amplifier.

71. The method of claim 70, wherein the power amplifier is configured for wireless power transfer.

72-74. (canceled)

75. The method of claim 66, wherein the securing post is coupled to the printed circuit board along the first side of the printed circuit board using at least one of soldering, gluing, welding, press fitting, and bolting.

76. The method of claim 66, wherein at least a portion of the securing post is electrically conductive.

77. The method of claim 76, wherein the securing post is electrically coupled to the heat producing component and serves as an electrical connection for the heat producing component.

78. The method of claim 66, wherein the heat producing component is included as part of a plurality of heat producing components disposed on the first side of the printed circuit board and the printed circuit board heat transfer path thermally couples the plurality of heat producing components to the securing post, the method further comprising:
absorbing heat generated by the plurality of heat producing components disposed on the first side of the printed circuit board; and
transferring to the securing post, through the printed circuit board heat transfer path, the heat generated by the plurality of heat producing components disposed on the first side of the printed circuit board.

79. The method of claim 78, wherein the securing post is included as part of a plurality of securing posts disposed on the first side of the printed circuit board, the plurality of securing posts thermally coupled to the plurality of heat producing components through one or more printed circuit board heat transfer paths including the printed circuit board heat transfer path, the method further comprising transferring to the plurality of securing posts, through the one or more printed circuit board heat transfer paths, the heat generated by the plurality of heat producing components disposed on the first side of the printed circuit board.

80. The method of claim 66, further comprising transferring the heat generated by the heat producing component from the securing post to the heat sink attached to the securing post along the first side of the printed circuit board through the fastening mechanism.

81. The method of claim 80, further comprising transferring the heat generated by the heat producing component from the securing post to the heat sink through a thermally conductive filler material disposed between a top of the securing post and a portion of the heat sink.

82. The method of claim 81, wherein the thermally conductive filler material is electrically conductive.

83-92. (canceled)

93. The method of claim 66, wherein the securing post is coupled to the printed circuit board along the first side of the printed circuit board through a coupling mechanism extending through a second side of the printed circuit board opposing the first side of the printed circuit board.

94. The method of claim 66, wherein the securing post is electrically coupled to one or more additional components separate from the heat producing component and serves as an electrical connection for the one or more additional components.

95. The method of claim 66, further comprising transferring the heat produced by the heat producing component through another heat transfer path thermally coupling the heat producing component to a component mounted on a second side of the printed circuit board opposing the first side of the printed circuit board as part of dissipating the heat generated by the heat producing component away from the heat producing component.

96. The method of claim 95, wherein the another heat transfer path is configured to transfer heat generated at the second side of the printed circuit board to the securing post on the first side of the printed circuit board.

97-126. (canceled)

127. The system of claim 1, wherein the printed circuit board includes a region adjacent to the securing post for physically receiving a post of the heat sink, wherein the region forms part of the printed circuit board heat transfer path and is configured to transfer the heat from the heat producing component to the heat sink through the post of the heat sink.

128. The method of claim 66, further comprising transferring the heat generated by the heat producing component to a region adjacent to the securing post and forming part of the printed circuit board heat transfer path, wherein the region adjacent to the securing post is configured to receive a post of the heat sink and transfer the heat from the heat producing component to the heat sink through the post of the heat sink.
